(19) United States
(12) Patent Application Publication
(10) Pub. No.: US 2017/0029940 A1
(43) Pub. Date: Feb. 2, 2017

(54) Sputter System for Uniform Sputtering

(71) Applicant: SOLERAS ADVANCED COATINGS BVBA, Deinze (BE)

(72) Inventors: Ivan VAN DE PUTTE, Waregem (BE); Niek DEWILDE, Kruishoutem (BE); Guy GOBIN, Oostende (BE); Wilmert DE BOSSCHER, Drongen (BE)

(21) Appl. No.: 15/304,132

(22) PCT Filed: Apr. 14, 2015
(86) PCT No.: PCT/EP2015/058006

§ 371 Date: Oct. 14, 2016

(30) Foreign Application Priority Data
Apr. 18, 2014 (BE) 2014/0275

(51) Int. Cl. C23C 14/54; C23C 14/35; H01J 37/34

(52) U.S. Cl. CPC C23C 14/545; H01J 37/3455; H01J 37/3423; H01J 37/347; H01J 37/3476; C23C 14/352; C23C 14/35; H01J 37/3405

(57) ABSTRACT

A sputter system for applying a coating on a substrate is described. The sputter system comprises at least two cylindrical sputter units for the joint sputtering of a single coating. Each sputter unit comprising an elongated magnet configuration and at least one elongated magnet configuration comprising a plurality of magnet structures and magnet structure control systems along the length direction of the elongated magnet configuration. At least one magnet structure is adjustable in position and/or shape by a magnet structure control system, while a sputter target is mounted on the sputter unit.

### FIELD OF THE INVENTION

The invention generally relates to systems and methods for applying a coating. More specifically, this invention relates to systems and methods for controlling the homogeneity of a parameter of the deposited coating on the substrate.

### BACKGROUND OF THE INVENTION

For a large number of applications, including flat panel display technology (TFT based on LCD or OLED technology), use is made of substrates, provided with one or more coatings. Such products can for example be produced by depositing coatings on the substrate by means of sputtering. In order to achieve the production of these products in an efficient way, sputtering is typically performed on large substrates, which can optionally be split afterwards. Typically two solutions are used for sputtering: Either the deposition is performed in a continuous or quasi-continuous manner, such as with in-line deposition systems, whereby the substrate moves relative to the sputter target. Or the deposition takes place while the substrate is substantially stationary with respect to the sputter target. In the latter case use is typically made of a deposition system with a large sputter target area, i.e. a system whereby the sputter target area has similar or larger dimensions than that of the substrate.

The quality of the sputtered products and the corresponding final products is determined inter alia by the number of defects and by the homogeneity of certain parameters of the applied layers.

The presence of particles during the sputtering process turns out to be an important source of defects. Tests have shown that the number of particles leading to defects is larger in sputter processes whereby the substrate moves than in sputter processes in which the substrate is substantially stationary. The use of a moving substrate is thus a source of particles, which particles remain in the substrate and thus disturb the deposited coatings. Consequently in the present invention the focus is on deposition systems in which a substantial stationary substrate is used.

As stated above, a second important aspect is the homogeneity of the deposited layer. A variation in one or more parameters of the deposited layer can give rise to a sub-optimal performance and variable quality of the final product, for example, a flat panel display. Consequently, high requirements are imposed on the homogeneity of the deposited layers.

Various types of variations in one or more parameters of the deposited layer may arise.

Variations in a parameter, for example the thickness of the coating, may increase or decrease systematically in one direction. These systematic variations can typically be divided into polynomial variations and periodic variations. The periodic variations may, for example, be specifically induced when a number of individual sputter targets are used which are placed in parallel next to each other so as to generate a large sputter target area. Depending on the position of the substrate relative to the plurality of targets, a different material flux may occur during the sputtering process.

In addition to periodic variations in a direction over several sputter targets, also other typical variations in material flux may occur. Near the ends of elongate sputter targets the material flux is typically different from that at other positions along the erosion profile of the sputter target.

In systems whereby multiple sputter targets are placed in parallel next to each other, moreover characteristic variations in sputter efficiency occur in certain corners of the common sputter target surface. These variations are caused by physical processes that occur in these specific configurations. The occurrence of these variations results in the fact that the resulting variations in one or more parameters of the deposited coating are not one-dimensional but are typically two-dimensional, and therefore are often much more difficult to control.

A lack of uniformity in one or more parameters of the coating may thus be caused by a non-uniform partial pressure of the used sputtering gas (argon or reactive gas), a non-uniform magnetic field distribution, a non-uniform distribution of the electric field, a non-uniform sputter target surface (for example, in morphology and/or composition) and/or by physical processes inherently present in the sputtering deposition system with a substantially stationary substrate.

Various techniques for reducing or preventing variations in homogeneity have already been suggested in the prior art. These techniques include:
introducing small movements of the magnets and/or the substrate in order to filter out small local variations, so as to introduce a homogeneous deposition,
using an optimal mechanical position/orientation of the sputter deposition systems so that a more optimal distribution of the deposited layer is obtained, for example, by adjusting the distance between each individual sputter target and the substrate and/or by adjusting the power per sputter target individually,
adjusting the gas distribution so as to obtain a uniform thickness of the coating in the longitudinal direction. Because of this, however, it can occur that layers with a different composition are formed.

Most of the proposed solutions can compensate for variations of a coating parameter in a single direction, but compensation in two dimensions is not or hardly possible.

One solution in the prior art proposes the use of a large planar sputter target with a two-dimensional matrix-controlled regulation of the underlying magnet structure, whereby a matrix of magnet configurations is each individually controllable. However, controlling such two-dimensional matrix of magnet configurations requires a complex adjustment at the expense of the efficiency of the deposition technique.

There remains a need for an efficient sputter deposition system and an efficient method for sputtering of a homogeneous coating on a substrate, in particular for sputtering a coating having a high two-dimensional uniformity.

### SUMMARY OF THE INVENTION

It is an object of the present invention to provide a system and a method that allows to adjust the homogeneity of the coating over the 2D substrate.

The above-mentioned objective is achieved by a device, system and/or a method according to the present invention.

The present invention relates to a sputtering system for depositing a coating on a substrate, the sputter system comprising: a substrate holder, on which a substrate can be positioned, so that the substrate is substantially stationary during the application of the coating,

at least two cylindrical sputter units for the joint sputtering of a single, e.g. one and the same coating, each sputter unit comprising an elongated magnet configuration,

wherein at least one elongated magnet configuration comprises a plurality of magnet structures and magnet structure control systems along the length direction of the elongated magnet configuration; wherein at least one magnet structure is controllable in position and/or shape by a magnet structure control system, while a sputter target is mounted on the sputter unit, in order to influence the homogeneity of the sputtered coating.

The magnetic structure may be a magnet array. Various magnet structures are typically located next to each other so that together they form the elongated magnet configuration. The elongated magnet configuration may thus typically consist of several mutually adjacent magnet structures extending over the length of the sputter target. It is an advantage of embodiments of the present invention that the variation in the homogeneity of a parameter of the coating can be made smaller than 20% or even less than 10% or even less than 5% of the average value of that parameter of the coating. That parameter may be the thickness, the resistivity, a parameter which characterizes an electric or optical property of the coating, etc. It is an advantage of embodiments of the present invention that this is also possible when the substrate is fixedly positioned relative to the sputter system. After all, in sputter systems with a moving substrate the risk of contamination of the coating is increased. During sputtering, the deposition rate of the target material on the substrate may alter locally. Moreover, there are typically also inherent differences in deposition rates in the various directions over the substrate. It is thus an advantage of embodiments of the present invention that the magnet structures of a magnet configuration, or of a plurality of magnet configurations can be positioned independently of each other, and that they can be operated during use, i.e. when the sputter target is mounted. The magnetic configurations may be controllable from a distance. The latter allows to modify the deposition rate while the sputter system is operational and/or while the sputter system is under vacuum. This allows to take into account an increasing contamination of the coater and/or a changing thickness of the sputter target (due to erosion). It is an advantage of embodiments of the present invention that the sputter target need not be removed in order to adjust the magnetic structures. This typically results in a gain in time.

At least part of the elongated magnet configurations may contain a plurality of magnet structures and magnet structure control systems along the length direction of the elongated magnet configurations, whereby a portion of the magnet structure is controllable in position and/or shape, remotely, by a magnet structure control system. It is an advantage of embodiments of the present invention that an accurate control of the homogeneity of a deposited later is possible.

The cylindrical sputter units may be oriented substantially in parallel with respect to each other.

The magnetic axis of the elongated magnet configuration of at least one of the sputter units may be configured parallel to the substrate, when the substrate is positioned in the substrate holder.

The influence of an individual adjustment in position and/or shape of a magnet structure of an elongated magnet configuration may only be sensible in the magnetic field vector over a fraction of the length of the elongated magnet configuration.

It is an advantage of embodiments of the present invention that a local adjustment of the magnetic field only has a limited impact on neighbouring parts of the sputter target or on neighbouring sputter targets. In contrast, a local adjustment of the magnetic field has a significant impact on the local magnetic field vectors. This allows to locally adjust the material flux vector of the target material on the substrate. With “locally” is meant in this case over a length which is at most half the length of the elongated magnet configuration. Dependant on the embodiment of the present invention, the field strength may be varied in such a way that the physical variation changes by plus or minus 40%.

One or more of the magnet structure control systems may be configured to adjust the position of the corresponding magnet structures.

The one or more magnet structure control systems may be configured to adjust the position of the corresponding magnet structures by rotating the corresponding magnet structures around a rotation axis in parallel with the longitudinal axis of the elongated magnet configuration.

It is an advantage of embodiments of the present invention that periodic variations in the thickness of the coating in transverse direction can be reduced by rotating the magnet structures. It is an advantage of embodiments of the present invention that the deposition rate of target material can be adjusted locally and continuously. This makes it possible to reduce the deposition rate at locations where otherwise too much target material would be deposited in the coating, and to increase the deposition rate at locations where otherwise not enough target material would be deposited in the coating.

The one or more magnet structure control systems may be configured to adjust the position of the magnet structures by shifting the magnet structure. In embodiments of the present invention, parts of the magnet structure may also move relative to each other. This creates more degrees of freedom to modify the magnetic field, as compared to the case where movement is not possible. It is an advantage of embodiments of the present invention that there are more degrees of freedom to adjust the magnetic field vectors, induced by a magnet structure.

One or more magnet structure control systems may be configured to adjust the shape of the corresponding magnet structures.

The one or more magnet structure control systems may be configured to adjust the shape of the corresponding magnet structures by shifting only part of the corresponding magnet structure. It is an advantage of embodiments of the present invention that both the magnitude and the direction or orientation of the magnetic field vectors can be adjusted. It is an advantage of embodiments of the present invention that the magnitude and direction or orientation of the magnetic field vectors can be adjusted along a length direction of the elongated magnet configurations and between different elongated magnet configurations. This enables a quick and easy adjustment of the deposition rate along the length direction of each individual magnet configuration and in a direction transverse to the different magnet configurations.

The one or more magnet structure control systems may be configured to adjust the shape of the magnet structures by rotating part of the corresponding magnet structure around a rotation axis parallel to the longitudinal axis of the elongated magnet configuration.

The one or more magnet structure control systems may be configured to adjust the shape of the magnet structures by differently rotating different portions of the corresponding magnet structure around a rotation axis parallel to the longitudinal axis of the elongated magnet configuration. It is an advantage of embodiments of the present invention that the magnetic field strength in a virtual plane perpendicular to the substrate and containing the rotation-axis can be reduced by rotation of two portions of one magnet structure away from the virtual plane. In this way it can be avoided that a thicker coating is created on the substrate at the location of the virtual plane. It is an advantage of embodiments of the present invention that it is not necessary to stop sputtering to adjust the orientation of parts of the magnet structure so as to avoid local thickening in the coating.

The cylindrical sputter units may comprise a cylindrical sputter target which is provided with a cylindrical cavity extending in the longitudinal direction of the cylinder axis, wherein the elongated magnet configuration can be positioned.

One or more magnet structure control systems may comprise a motor and embedded electronics. One or more magnet structure control systems may also comprise a sensor for position determination. It is an advantage of embodiments of the present invention that the positioning of the magnet configurations can be accomplished by means of components which are configurable from a distance. It is thus not necessary to stop the sputter process, or to open the sputter system, or to remove the sputter target in order to adjust the positioning of the magnet configurations.

The one or more magnet structure control systems may also comprise an actuator for converting the movement of the motor in a translation movement and/or a rotation movement of the corresponding magnet structure.

The sputter system may comprise a controller for controlling magnet structure control systems in the plurality of elongated magnet configurations, the controller being adapted for, when controlling elements from one magnet configuration, to also take into account the control of elements from one or more of the other magnet configurations.

Each elongated magnet configuration may comprise a control unit for controlling the plurality of magnet structure control systems for controlling the plurality of magnet structures. It is an advantage of embodiments of the present invention that a single control unit per magnet compartment is sufficient to drive the various magnet positioning systems. The sputter system may also comprise a central control unit, whereby the central control unit is operatively connected to each of the control units. It is an advantage of some embodiments of the present invention that all magnet positioning systems may be controlled via a single central control unit. This makes a continuous central adjustment of the sputter process possible.

The sputter system may comprise a monitoring system for monitoring a particular characteristic of a sputtered coating on a plurality of positions in different directions over the coating.

The monitoring system may be connected to the controller in a feedback loop, such that the controller can adjust the control as a function of the measured parameter values.

At least one magnet structure may be controllable in position and/or shape by a magnet structure control system, so as to influence the homogeneity of the sputtered coating in at least two different dimensions over the coating.

The present invention also relates to a method for sputtering a coating on a substrate, the method comprising,
adjusting a plurality of magnet structures of at least one elongated magnet configuration of a cylindrical sputter unit in a system comprising at least two cylindrical sputter units, by adjusting the position and/or the shape of at least one magnet structure, while a sputter target is mounted on the sputter unit, in order to influence the homogeneity of the sputtered coating. It is an advantage of embodiments of the present invention that the position of the magnet configurations can be adjusted during sputtering. After all, this makes it possible to obtain a uniform coating of the sputter material on the substrate.

The method may furthermore comprise monitoring the homogeneity of a parameter of the coating at a plurality of positions over the sputtered coating, and adjusting the plurality of magnet structures as a function of the measured parameters of the coating.

Particular and preferred aspects of the invention are set out in the accompanying independent and dependent claims. Features from the dependent claims may be combined with features of the independent claims and with features of other dependent claims as appropriate and not merely as explicitly set out in the claims.

These and other aspects of the invention will be apparent from and elucidated with reference to the embodiment(s) described hereinafter.

### SHORT DESCRIPTION OF THE DRAWINGS

FIG. 1 shows an embodiment of a sputter system according to an embodiment of the present invention.

FIG. 2 is a schematic representation of a cross-sectional in a plane perpendicular to the longitudinal direction of a configuration of a magnet structure, according to an embodiment of the present invention.

FIG. 3 is a schematic representation of a possible rotation of a configuration of a magnet structure, according to an embodiment of the present invention.

FIG. 4 is a schematic representation of a configuration of a magnet structure consisting of multiple sub-configurations which can be moved independently from each other, according to an embodiment of the present invention.

FIG. 5 is a schematic representation of a possible rotation around two axes of a configuration of a magnet structure consisting of multiple sub-configurations, according to an embodiment of the present invention.

FIG. 6 is a schematic representation of a possible rotation around one rotation-axis of a configuration of a magnet structure consisting of multiple sub-configurations, according to an embodiment of the present invention.

FIG. 7 is a schematic representation of a possible rotation around one rotation-axis of a configuration of a magnet structure consisting of multiple sub-configurations, according to an embodiment of the present invention.

FIG. 8 is a schematic representation of a configuration of a magnet structure consisting of multiple sub-configurations which can be moved independently from each other, according to an embodiment of the present invention.

FIG. 9 is a schematic representation of a possible displacement of a sub-configuration of a configuration of a magnet structure relative to the other sub-configurations, according to an embodiment of the present invention.

FIG. 10 is a schematic representation of a sputter system according to an embodiment of the present invention.

FIG. 11 is a 3D-drawing of a magnet positioning system according to an embodiment of the present invention.

FIG. 12 shows the sequence of different steps of a method according to an embodiment of the present invention.

The drawings are only schematic and are non-limiting. In the drawings, the size of some of the elements may be exaggerated and not drawn on scale for illustrative purposes.

Any reference signs in the claims shall not be construed as limiting the scope. In the different drawings, the same reference signs refer to the same or analogous elements.

### DETAILED DESCRIPTION OF ILLUSTRATIVE EMBODIMENTS

The present invention will be described with respect to particular embodiments and with reference to certain drawings but the invention is not limited thereto but only by the claims. The drawings included and described herein are schematic and are not limiting the scope of the invention. It is also noted that in the drawings, the size of some elements may be exaggerated and, therefore, not drawn to scale for illustrative purposes. The dimensions and the relative dimensions do not correspond to actual reductions to practice of the invention.

Furthermore, the terms first, second, third and the like in the description and in the claims, are used for distinguishing between similar elements and not necessarily for describing a sequence, either temporally, spatially, in ranking or in any other manner. It is to be understood that the terms so used are interchangeable under appropriate circumstances and that the embodiments of the invention described herein are capable of operation in other sequences than described or illustrated herein.

Moreover, the terms top, bottom, above, front and the like in the description and the claims are used for descriptive purposes and not necessarily for describing relative positions. It is to be understood that the terms so used are interchangeable under appropriate circumstances and that the embodiments of the invention described herein are capable of operation in other orientations than described or illustrated herein.

It is to be noticed that the term “comprising”, used in the claims, should not be interpreted as being restricted to the means listed thereafter; it does not exclude other elements or steps. It is thus to be interpreted as specifying the presence of the stated features, integers, steps or components as referred to, but does not preclude the presence or addition of one or more other features, integers, steps or components, or groups thereof Thus, the scope of the expression “a device comprising A and B” should not be limited to devices consisting only of components A and B. It means that with respect to the present invention, the only relevant components of the device are A and B.

Reference throughout this specification to “one embodiment” or “an embodiment” means that a particular feature, structure or characteristic described in connection with the embodiment is included in at least one embodiment of the present invention. Thus, appearances of the phrases “in one embodiment” or “in an embodiment” in various places throughout this specification are not necessarily all referring to the same embodiment, but may. Furthermore, the particular features, structures or characteristics may be combined in any suitable manner, as would be apparent to one of ordinary skill in the art from this disclosure, in one or more embodiments.

Similarly it should be appreciated that in the description of exemplary embodiments of the invention, various features of the invention are sometimes grouped together in a single embodiment, figure, or description thereof for the purpose of streamlining the disclosure and aiding in the understanding of one or more of the various inventive aspects. This method of disclosure, however, is not to be interpreted as reflecting an intention that the claimed invention requires more features than are expressly recited in each claim. Rather, as the following claims reflect, inventive aspects lie in less than all features of a single foregoing disclosed embodiment. Thus, the claims following the detailed description are hereby expressly incorporated into this detailed description, with each claim standing on its own as a separate embodiment of this invention.

Furthermore, while some embodiments described herein include some but not other features included in other embodiments, combinations of features of different embodiments are meant to be within the scope of the invention, and form different embodiments, as would be understood by those in the art. For example, in the following claims, any of the claimed embodiments can be used in any combination.

In the description provided herein, numerous specific details are set forth. However, it is to be understood that embodiments of the invention may be practised without these specific details. In other instances, well-known methods, procedures and techniques have not been described in detail, so as not to obscure the present invention.

In a first aspect, the present invention relates to a sputter system for applying a coating on a substrate. The sputter system thereby typically comprises a substrate holder, whereto, e.g. upon which a substrate can be positioned, so that the substrate is substantially stationary during the application of the coating. Where in the present invention reference is made to “substantially stationary substrate”, what is meant is that the average position of the substrate remains constant during the sputter process. Small position variations of the substrate, for example as an additional action to obtain a more uniform deposition of the coating, also fall within the definition that the substrate is substantially stationary. Movement of the substrate as is typically used in a continuous in-line deposition system does not fall within the definition of a substantially stationary substrate, because in this case the substrate will not be at the same position relative to the sputter source at two different moments in time. The same applies for movement of the substrate wherein there is an overall movement of the substrate overt time. ²The sputter system according to embodiments of the present invention furthermore comprises at least two cylindrical sputter units. In a preferred embodiment the sputter system comprises a set of parallel cylindrical sputter units, closely positioned next to each other. Each sputter unit thereby comprises an elongated magnet configuration. The axes in the length direction of the elongated magnet configurations may all be located at an equal distance from the substrate, or may, in other embodiments, have a different distance to the substrate. Even the axis of a single elongated magnet configuration need not have a constant distance relative to the substrate, in other words, the elongated magnet configuration may be tilted with respect to the plane defined by the substrate.

At least one elongated magnet configuration comprises a plurality of magnet structures and magnet structure control systems along the length direction of the elongated magnet configuration. In embodiments of the present invention at least one magnet structure is adjustable in position and/or shape by a magnet structure control system, while a sputter target is mounted on the sputter unit. In a preferred embodiment, magnet structures of multiple elongated magnet configurations are adjustable in position and/or shape. In some embodiments, magnet structures are remotely adjustable in position and/or shape. In some embodiments this is even possible while water cooling for the sputter unit is connected, or even while the cooling system is operational and cooling liquid is circulating, or even while the sputter target is being electrically powered, or even during sputtering with the sputter unit. Controlling the position and/or shape of at least one magnet structure may result in influencing and improving the homogeneity of the sputtered coating over the substrate. The magnet structure control system may be operable remotely, from a distance. It is an advantage of embodiments of the present invention that it allows to adjust the position of the magnet configurations during sputtering and/or when the sputtering is for example temporarily interrupted but the sputter system 100 is still under vacuum.

It is a particular advantage of embodiments of the present invention that variations in the coating in one or two dimensions over the surface of the substrate can be reduced or avoided.

In embodiments of the present invention typically sputter targets will be positioned between the magnet configurations and the substrate. The sputter targets used in systems according to the present invention are typically cylindrical sputter targets. It is an advantage of embodiments of the present invention that it is not necessary to remove the sputter targets prior to adjustment of the magnet configurations.

In embodiments of the present invention, some or all of the magnet structures in one or more elongated magnet configurations may be individually controlled. The magnet structure control systems may be configured in such a way that they can control individual magnet structures or a group of magnet structures.

Where in the present invention reference is made to controlling a magnet structure, or more specifically to controlling the position and/or shape thereof, this can mean selecting a shape or position, or can mean effectively configuring the magnet structure so that the latter obtains a specific shape or position. Adjusting the shape or position of a magnet structure comprises adjusting the distance to the sputter target and/or adjusting the orientation of the magnet structure. Adjusting the orientation allows to change the direction of the magnetic field vectors. Adjusting the distance to the sputter target surface allows to change the magnetic field strength. Each of these adjustments allows to change the material flux vector locally and in a controlled manner.

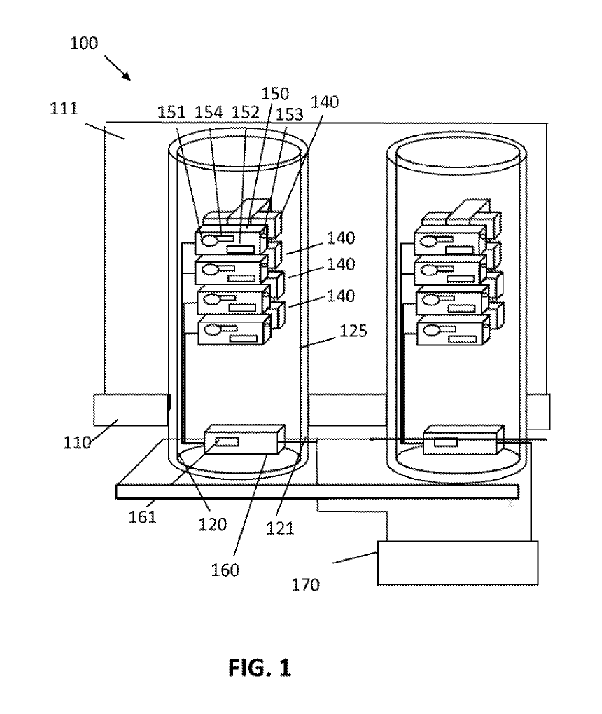

By way of illustration, embodiments of the present invention not being limited thereto, standard and optional features of some embodiments of the sputter system 100 are illustrated, referring to FIG. 1 to FIG. 11.

FIG. 1 shows a possible embodiment of the present invention showing a sputter system 100. In the present example only two sputter units 125 are shown in order not to overload the drawing, but it will be clear for the skilled person that in some embodiments of the present invention three, or more than three sputter units 125 may be present. In the embodiment of FIG. 1 the sputter unit 125 comprises an elongated magnet configuration with a plurality of magnet structures 140. In the embodiment the elongated magnet configuration comprises a plurality of magnet structures 140 and magnet structure control systems 150, whereby in the present example one magnet structure control system 150 is provided for each magnet structure 140, although embodiments of the present invention are not limited thereto, and different magnet structures 140 may also be controlled via a common magnet structure control system 150. In the embodiment of FIG. 1 each magnet structure control system comprises a positioning system such as for example a servo motor 151, an embedded control electronics 152, a sensor for position determination 153 and a conversion system 154. The conversion system 154 converts the rotational movement of the servo motor 151 into a movement that provides the desired shape or position of the magnet structure 140. The servo motor 151 may for example be a brushless DC motor. The various sputter units in FIG. 1 furthermore comprise a common control unit or different control units 160. The control unit 160 is the central point from where the various magnet structure control systems 150 may be controlled independently from one another. The control unit 160 is thus typically connected with each of the magnet structure control systems 150, and allows to control the different magnet structure control systems 150. This connection may be a mechanical connection, but a communication interface with an embedded control electronics 152 is also possible. The control unit 160 is the central point from where the various magnet positioning systems can be controlled. The control unit 160 may comprise a central processing unit (CPU) 161 that supports communication with the outside world and with the magnet structures 140. The control unit may for example transmit a desired position to the embedded control electronics 152 of one of the magnet structure control systems 150. The embedded control electronics 152 may then in turn control the servo motor 151 based on position information obtained from the sensor 153 and based on the desired position. The desired position can be entered by the user via the control unit 160. The sensor for position determination 153 may be an optical sensor. The position can in some embodiments also be determined by means of coded-pulses from the servo motor 151, which may be a brushless DC-motor.

In some embodiments of the present invention, movement of the servo motor 151 is converted by a conversion system 154 into a translation movement or a rotational movement or a combination of both. Such a conversion system 154 may be a gear box. The magnet structure control system 150 may also—under some circumstances, e.g. when a good fixed setting is found—be frozen to guarantee a certain position of the magnet configuration 140. In some embodiments, an anti-rotation block 1101 is provided for this purpose.

In the embodiment of the present invention shown in FIG. 1, communication is possible between the control unit 160 and the central control unit 170. The physical link for this communication can be realized in different ways, such as for example via cable, glass fibre, plastic fibre, wireless, such as for example described in international patent application WO2013/120920.

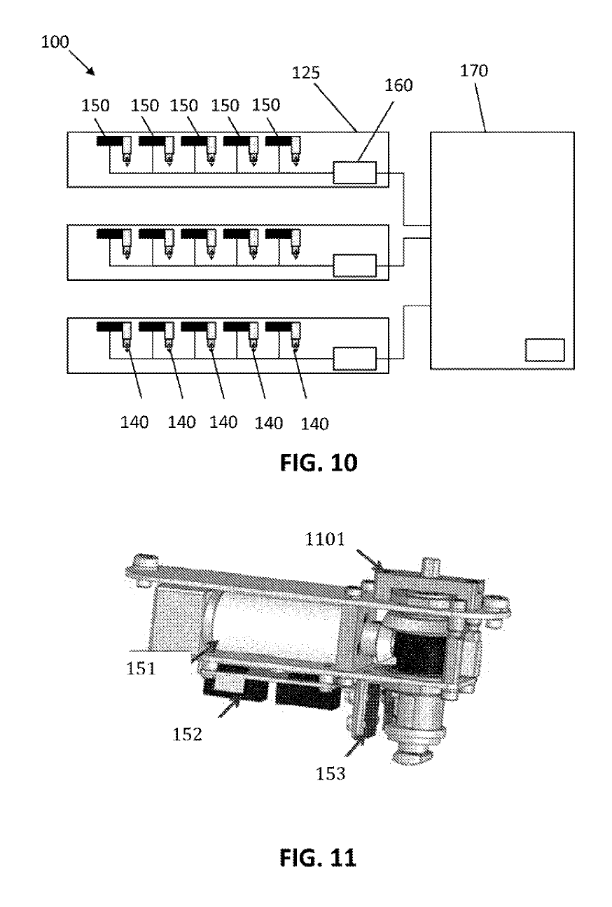

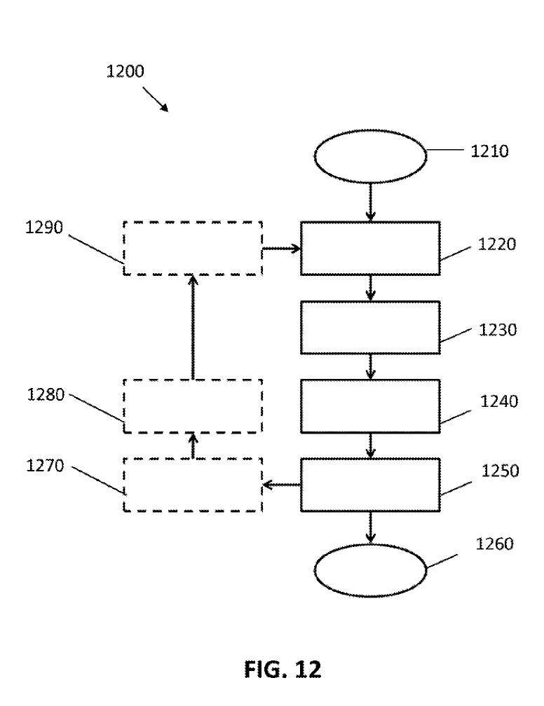

In this way, each of the magnet structure control systems 150 can be controlled via the central control unit 170. By providing the necessary interface (e.g. user interface), in this way the user has control over the sputter process. An example of a central control unit 170 which is connected to multiple control units 160 is schematically represented in FIG. 10.

FIG. 1 also shows a sputter target holder 120 whereto, e.g. upon which a sputter target 121 is mounted. The sputter target in FIG. 1 is in the present embodiment a cylindrical sputter target, and is located around the cylindrical magnet compartment 125. The sputter target of FIG. 1 also comprises a substrate holder 110 upon which a substrate 111 is positioned. The axis of the elongated magnet configuration is in the present example, parallel to the substrate, but embodiments of the present invention are not limited thereto.

In embodiments of the present invention the adjustment of the position or shape of a magnet structure 140 is only perceptible or sensible in the magnetic field over a fraction of the length of the elongated magnet configuration in the sputter unit 125. This fraction may for example be smaller than 50% of the length of the elongated magnet configuration. The fraction over which an adjustment can be sensed is typically related to the number of magnet structures 140 present per elongated magnet configuration. The larger the number of magnet structures 140, the smaller the distance of sensibility may be. As a consequence, by using a larger number of magnet structures, the magnetic field can be adjusted with a finer resolution. It is then an advantage of embodiments of the present invention that both the magnitude and the direction or orientation of the magnetic field vectors can be locally adjusted.

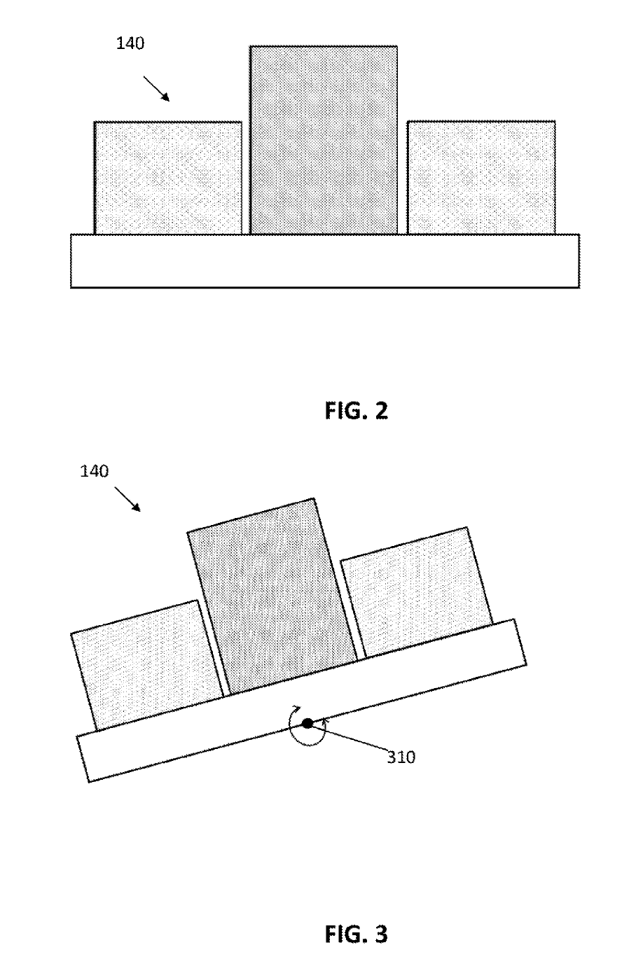

In particular embodiments of the present invention the magnet structure control system 150 may be configured to rotate the magnet structure 140 around a rotation-axis 310 parallel to the axis of the elongated magnet structure. The angular range over which can be rotated is at least between −60° and +60°, or preferably at least between −30° and +30°. In embodiments of the present invention, the rotation has an accuracy of 1°, or better than 1°. A possible embodiment hereof, is schematically illustrated in FIG. 3. FIG. 3 shows a cross section of a magnet structure 140 and a rotation-axis 310 around which the magnet structure can rotate. In this embodiment the entire magnet structure 140 rotates as a whole. In embodiments of the present invention, the individual magnet structures 140 may be rotated independently from one another. FIG. 2 to FIG. 9 show various possibilities of motion of a magnet configuration 140 according to embodiments of the present invention. FIG. 2 thereby shows a basic magnet structure 140 providing the basis for these examples. In FIG. 5 to FIG. 9 this basic magnet structure is divided in a number of sub-configurations 410 according to different embodiments of the present invention. In the example of FIG. 3 the position of the magnet structure 140 can be adjusted successively in such a way that the coating on the substrate is as even as possible.

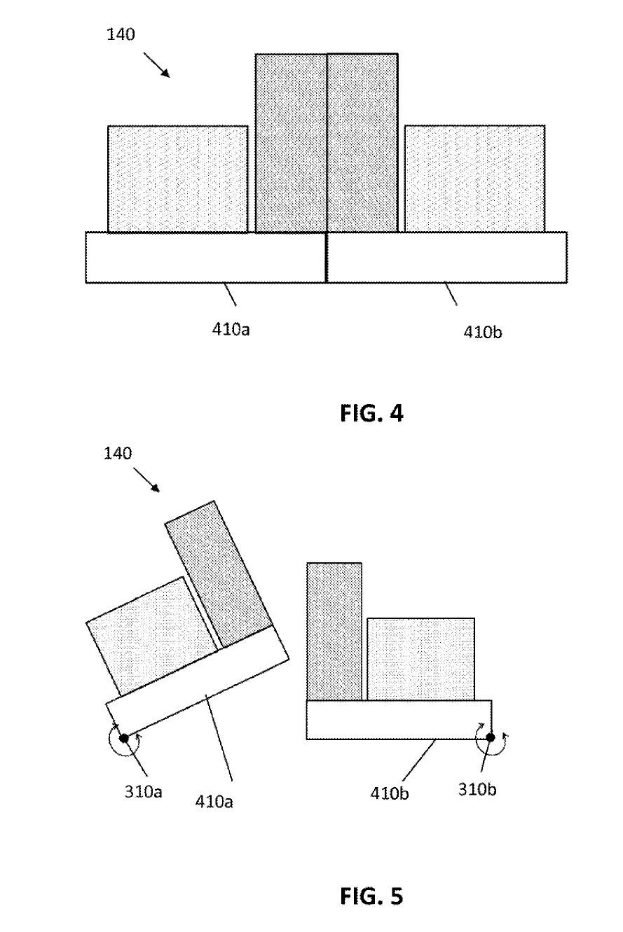

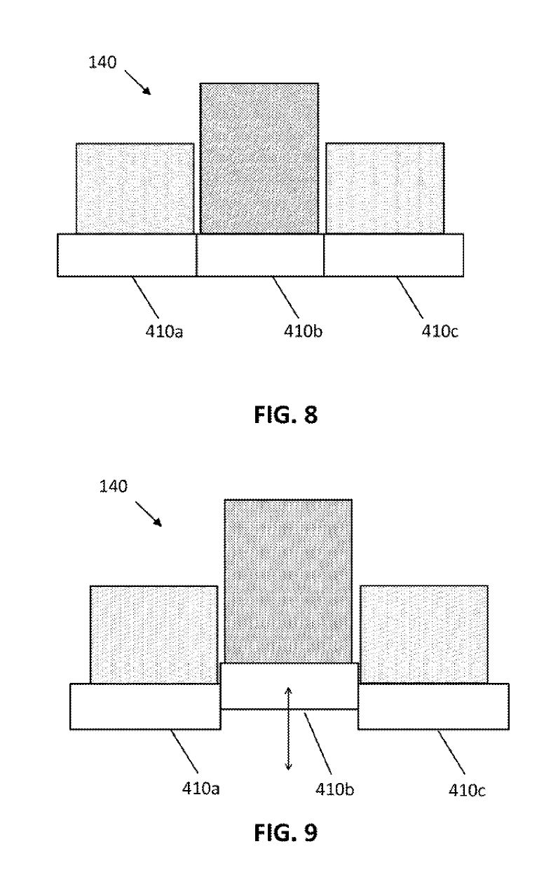

Optionally the magnet structures 140 of the sputter system 100 can be divided in several sub-configurations 410. These sub-configurations may then be moved individually. The sub-configurations can be moved relatively to each other in such a way, e.g. to such an extent, that they do not hinder each other's movement. A possible division in sub-configurations is illustrated in FIG. 4. In this drawing the magnet configuration 140 is divided in two symmetrical sub-configurations 410, a first sub-configuration 410a and a second sub-configuration 410b. Another example is illustrated in FIG. 8, where the magnet structure 140 is subdivided in three sub-configurations 410, a first sub-configuration 410a, a second sub-configuration 410b, and a third sub-configuration 410c. Splitting into sub-configurations allows to move the sub-configurations independently from one another, which offers the advantage that the magnet field distribution can be adjusted in a more flexible manner.

More specifically, in an embodiment of the present invention, the magnet configuration 140 is divided in a first sub-configuration 410a and a second sub-configuration 410b. The first sub-configuration 410a can thereby rotate around a first rotation-axis 310a parallel to the magnet compartment-axis, and the second sub-configuration 410b can rotate around a second rotation-axis 310b parallel to the magnet compartment-axis. An example of such an embodiment of the present invention is shown in FIG. 5. The first and the second rotation-axis 310a and 310b are located in this case on the outer corners of the first and second sub-configurations 410a and 410b. To this end, in these embodiments, the extreme corners located furthest from the substrate, are taken.

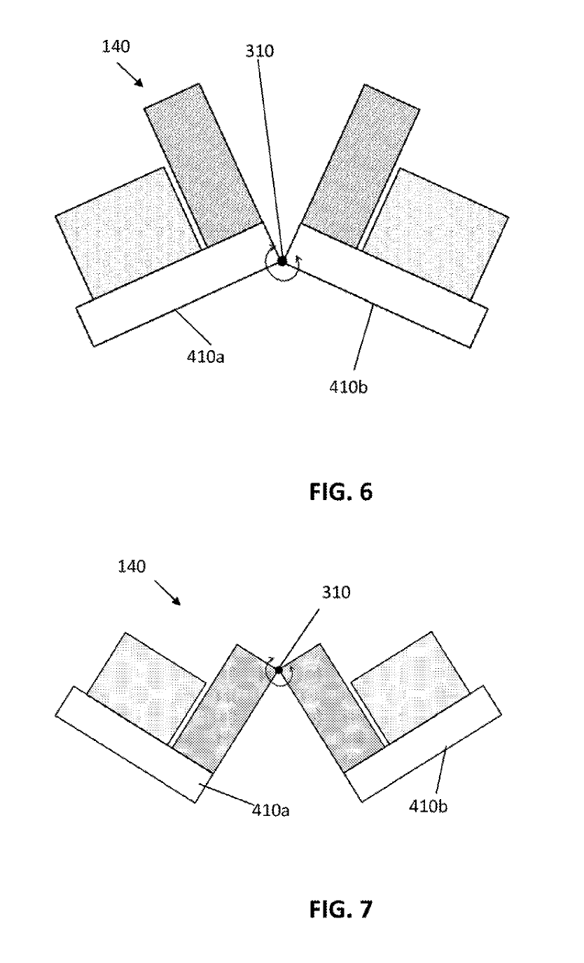

In yet another embodiment of the present invention the first rotation axis 310a and the second rotation axis 310b coincide. Examples thereof are illustrated in FIG. 6 and FIG. 7. In the embodiment illustrated in FIG. 6, the magnet structure 140 is divided in two symmetrical parts. The partition plane is hereby a plane perpendicular to the substrate 111. The rotation-axis 310 around which both parts rotate is the common rib of both sub-configurations 410a and 410b, which rib is located op the partition plane, and is located furthest from the substrate 111. By rotating the first sub-configuration 410a and the second sub-configuration 410b, the magnetic field induced by both magnet configurations can be adjusted. When for example the coating of the substrate opposite both sub-configurations in the length direction of the magnet compartment is thinner than the rest of the coating, it is possible to turn both sub-configurations away, so that the material flux vector opposite the magnet configuration 410 is reduced. In embodiments of the present invention, such as for example shown in FIG. 7, the rotation-axis 310 around which both sub-configurations 410a and 410b rotate, is the common rib of both sub-configurations 410a and 410b. The rib is located on the partition plane between both sub-configurations, and is the rib located closest to the substrate 111.

In embodiments of the present invention the magnet structure 140 can be shifted by the magnet structure control system 150. By shifting the magnet structure away from the sputter target surface, the material flux vector of the target material can be reduced at the location of the magnet structure 140. In case the plurality of magnet structures within a same magnet compartment can be moved independently from one another, this allows to adjust the material flux vector in the length direction of the elongated magnet configuration in the sputter unit 125. Consequently, it is an advantage of embodiments of the present invention that the material flux vector cannot only be adjusted between the different sputter units, but also in the length direction of the sputter units. Furthermore, the magnet structure 140 is in certain embodiments of the present invention divided in sub-configurations which can be shifted independently from one another. An example hereof is illustrated in FIG. 8 and FIG. 9. FIG. 8 shows a magnet configuration 140 which is divided in three sub-configurations 410a, 410b, 410c. The partition planes hereof are planes which are oriented perpendicular to the substrate 111. In this example, as illustrated in FIG. 9, the middle sub-configuration 410b can be shifted by the magnet structure control system 150. Due to the fact that only a sub-configuration is shifted, it is possible to adjust both the magnitude as well as the direction or the orientation of the magnetic field vectors in the vicinity of the magnet structure 140. With “vicinity” is meant the area or space wherein an adjustment of a position and/or shape of a magnet structure 140 can be sensed. These degrees of freedom in the adjustments of the magnetic field make it possible to obtain a coating with a thickness, whereby a variation of the thickness is less than 1% of the total thickness of the coating. Variation of other parameters, such as for example resistivity, can also be controlled in this manner. Furthermore these degrees of freedom in adjustments of the magnetic field allow to control one or more parameters of the coating in different dimensions. This may comprise control in two dimensions in the plane of the substrate.

In embodiments of the present invention, the magnet configuration 140 can be shifted as a whole.

In embodiments of the present invention the magnet structure 140 or a sub-configuration thereof can be adjusted over a distance of 10 mm with an accuracy of 0.1 mm, or even better.

In sputter systems 100 according to embodiments of the present invention, it is possible to apply target material. To this end, a sputter target holder 120 is present in the sputter system 100. This sputter target holder 120 makes it possible to mount a sputter target 121 between a magnet compartment 125 and a substrate 111. The latter may be positioned on a substrate holder 110. In embodiments of the present invention there is one sputter target holder 120 per sputter unit 125. Each sputter target holder 120 thereby allows to mount a cylindrical sputter target 121 to the corresponding sputter unit 125. Moreover, in particular embodiments of the present invention it is possible to rotate the sputter targets 121 by means of the sputter target holders 120. An example of a sputter target holder 120 for a cylindrical sputter target 121 is illustrated in FIG. 1.

FIG. 11 is a 3D schematic drawing of a magnet structure control system 150 according to an embodiment of the present invention. The magnet structure control systems 150 comprises a servo motor 151 which is controlled by the embedded control electronics 152. The position of the servo motor can be determined by means of a sensor 153. The movement may be fixed at a certain position by means of an anti-rotation block 1101.

In preferred embodiments of the present invention, the mechanical connections, the communication interconnections and the power interconnections are automatically established when mounting the magnet compartment.

In preferred embodiments of the present invention furthermore a cooling system is present for cooling the sputter targets 121 and the magnet structures 140. Other components which are typically comprised in a sputter unit and are known to the skilled person may also be incorporated in the system.

In a second aspect, the present invention relates to a method 1200 for sputtering a coating on a substrate 111. The method allows to obtain a better homogeneity of a parameter of the deposited coating. Such parameter may be the thickness, but may also be another physical parameter such as for example the resistivity or another electrical parameter, an optical parameter, etc.

The method 1200 of sputtering a coating on a substrate typically comprises arranging a substrate opposite the sputter target material, whereafter the sputter process is started. In order to obtain an even coating on the substrate, the position and/or shape of the magnet structures 140 may be adjusted during the sputter process.

Optionally it is also possible to adjust the position and/or shape of the magnet structures 140, between the time of sputtering a coating on the first substrate and the time of sputtering of a coating on the second substrate, but after inspection of the first substrate. The adjustment of the magnet structures 140 may also be performed during the sputtering of the coating on the second substrate, after inspection of the coating on the first substrate. The inspection of the substrate and the suitable adjustment of the magnet structures 140 may be performed manually or in an automatised manner, via algorithms and logical processors.

The method 1200 makes use 1210 of a sputter system, wherein individually controllable magnet structures 140 (e.g. remotely controllable) are present.

Thereafter a substrate can be provided 1220 and the sputter process can be started. The method typically comprises adjusting 1240 of the position of the magnet structures while the sputter targets are mounted on the sputter units. This may be on a non-operational sputter system, or on an operational sputter system, i.e. during sputtering. Preferably the adjustment can take place while the system is under vacuum, so that the vacuum need not be broken for performing the adjustment. The adjustment can preferably also take place while the water cooling is connected. In some embodiments the controlling can also take place while the sputter target is being powered, or during sputtering. By modifying the position and/or the shape of one or more magnet structures, both the amplitude as well as the orientation of the material flux vector can be adapted. As the positions and shape of the magnet structures can be changed independently from one another, the magnetic field vectors can be adjusted locally. The magnetic field vectors have a direct effect on the local material flux vectors of the target material on the substrate, so that these can also be adjusted locally. By locally adjusting the material flux vector, a homogeneous coating can be obtained on the substrate. This may comprise a homogeneity in thickness, but may also comprise a homogeneity in another parameter such as resistivity or another electrical parameter, an optical parameter, etc.

In a subsequent step the substrate is removed 1250, whereafter optionally sputtering can be resumed on a next substrate, or whereafter the sputter process may be stopped 1260.

Further optional steps may comprise or be associated with the inspection 1270 of the coating on a substrate for improving subsequent sputter processes. Based on the results of previously deposited coatings, the adjustment step 1240 may be updated, e.g. fine-tuned. This can be achieved manually or in an automated manner. Also the initial positions of the magnet configurations can be adjusted 1290 prior to providing the next substrate 1290, and starting the next sputter process 1230.

The various aspects can be easily combined with each other, and the combinations thus also correspond to embodiments of the present invention.

1-22. (canceled)

23. A sputter system for applying a coating on a substrate, the sputter system comprising:
a substrate holder, upon which a substrate can be positioned, in such a way that the substrate is substantially stationary during the application of the coating;
at least two cylindrical sputter units for the joint sputtering of a coating, each sputter unit comprising an elongated sputter magnet configuration;
wherein at least one elongated magnet configuration comprises a plurality of magnet structures and magnet structure control systems along the length direction of the elongated magnet configuration, wherein at least one magnet structure is adjustable in position and/or shape by a magnet structure control system, while a sputter target is mounted on the sputter unit, in order to influence the homogeneity of the sputtered coating on the substrate.

24. A sputter system according to claim 23, wherein at least part of the elongated magnet configurations comprises a plurality of magnet structures and magnet structure control systems along the length direction of the elongated magnet configurations, whereby a part of the magnet structure is remotely adjustable in position and/or shape by a magnet structure control system.

25. A sputter system according to claim 23, wherein the cylindrical sputter units are oriented substantially parallel with respect to each other.

26. A sputter system according to claim 23, wherein the magnetic axis of the elongated magnet configuration of at least one of the sputter units is configured parallel to the substrate, when the substrate is positioned in the substrate holder.

27. A sputter system according to claim 23, wherein the influence of an individual adjustment in position and/or shape of a magnet structure of an elongated magnet configuration is only detectable in the magnetic field vector over a fraction of the length of the elongated magnet configuration.

28. A sputter system according to claim 23, wherein one or more magnet structure control systems is/are configured to adjust the position of the corresponding magnet structures.

29. A sputter system according to claim 28, wherein the one or more magnet structure control systems is/are configured to adjust the position of the corresponding magnet structures by rotating the corresponding magnet structures around a rotation axis parallel to the longitudinal axis of the elongated magnet configuration.

30. A sputter system according to claim 28, wherein the one or more magnet structure control systems is/are configured to adjust the position of the magnet structures by shifting the magnet structures.

31. A sputter system according to claim 23, wherein one or more magnet structure control systems is/are configured to adjust the shape of the corresponding magnet structures.

32. A sputter system according to claim 31, wherein the one or more magnet structure control systems is/are configured to adjust the shape of the corresponding magnet structures by shifting only part of the corresponding magnet structures and/or wherein the one or more magnet structure control systems are configured to adjust the shape of the corresponding magnet structures by rotating a part of the corresponding magnet structure around a rotation axis parallel to the longitudinal axis of the elongated magnet configuration.

33. A sputter system according to claim 31, wherein the one or more magnet structure control systems is/are configured to adjust the shape of the magnet structures by differently rotating individual parts of the corresponding magnet structure around a rotation axis parallel to the longitudinal axis of the elongated magnet configuration.

34. A sputter system according to claim 23, wherein the cylindrical sputter units comprise a cylindrical sputter target, the cylindrical sputter target being provided with a cylindrical cavity extending in the longitudinal direction of the cylinder axis, inside which cavity the elongated magnet configuration can be positioned.

35. A sputter system according to claim 23, wherein one or more magnet structure control systems comprise a motor and an embedded control electronics.

36. A sputter system according to claim 35, wherein the one or more magnet structure control systems further comprise an actuator for converting the movement of the motor in a translation movement and/or a rotational movement of the corresponding magnet structure.

37. A sputter system according to claim 23, wherein the sputter system comprises a controller for controlling magnet structure control systems in the plurality of elongated magnet configurations, the controller being adapted for, when controlling elements from one magnet configuration, to also take into account the control of elements from one or more of the other magnet configurations.

38. A sputter system according to claim 23, wherein each elongated magnet configuration comprises a control unit for controlling the plurality of magnet structure control systems for controlling the plurality of magnet structures and/or wherein at least one magnet structure is controllable in position and/or shape by a magnet structure control system so as to influence the homogeneity of the sputtered coating in at least two different dimensions of the coating.

39. A sputter system according to claim 23, wherein the sputter system further comprises a monitoring system for monitoring a characteristic of a sputtered coating at a plurality of positions in different directions over the coating.

40. A sputter system according to claim 39, wherein the monitoring system is connected with a controller in a feedback loop, such that the controller can adjust the control as a function of the measured value of the specific parameter.

41. A method for sputtering a coating on a substrate, the system comprising,
adjusting a plurality of magnet structures of at least one elongated magnet configuration of a cylindrical sputter unit in a system comprising at least two cylindrical sputter units, by adjusting the position and/or the shape of at least one magnet structure, while a sputter target is mounted on the sputter unit, in order to influence the homogeneity of the sputtered coating.

42. A method according to claim 41, wherein the method furthermore comprises monitoring the homogeneity of a parameter of the coating at a plurality of positions over the sputtered coating, and adjusting the plurality of magnet structures as a function of the measured parameter of the coating.
